(19) United States
(12) Patent Application Publication
(10) Pub. No.: US 2015/0014825 A1
(43) Pub. Date: Jan. 15, 2015

(54) ESD PROTECTION DEVICE

(71) Applicant: UNITED MICROELECTRONICS CORP., Hsin-Chu City (TW)

(72) Inventors: Chao-Hua Cheng, Hsinchu City (TW); Wei-Szu Chen, Taipei City (TW)

(21) Appl. No.: 13/941,549

(22) Filed: Jul. 15, 2013

(51) Int. Cl. H01L 29/36

(52) U.S. Cl. CPC H01L 29/36
USPC 257/655

(57) ABSTRACT

An ESD protection device includes a substrate having a first conductive type. A doped well having a second conductive type is disposed in the substrate. A first doped region having the first conductive type is disposed in the doped well. A second doped region having the first conductive type is disposed in the substrate, wherein part of the second doped region is in the doped well, and the remaining part of the second doped region is separate from the doped well. A front terminal electrically connects the first doped region. A back terminal is disposed on a back side of the substrate.

### BACKGROUND OF THE INVENTION

1. Field of the Invention

The present invention relates to an electrostatic discharge (ESD) protection device. In particular, the present invention relates to an ESD protection device having an equivalent positive clamp voltage and negative clamp voltage.

2. Description of the Prior Art

Electrostatic discharge (ESD) is a major factor in the damage of electronic elements or electronic systems from electrical overstress (EOS). The damaged electronic elements or electronic systems maybe either temporarily disabled or permanently destroyed. This unexpected electrical overstress destruction and resultant damage to electronic elements not only adversely influences the integrated circuits (IC) but may, in extreme cases, cause the electronic products to fail to function.

Electrostatic discharge has many causes and is, for the most part, inevitable. Static charges may accumulate in human bodies, devices and storages equipment during the manufacture, assembly, testing and storage of electronic elements or electronic systems. Even the electronic elements themselves may accumulate static charges.

Therefore, it is desirable to have an ESD protection device which can protect electrostatic-sensitive devices from damage due to common static charges.

### SUMMARY OF THE INVENTION

The present invention provides an ESD protection device which includes a substrate having a first conductive type. A doped well having a second conductive type is disposed in the substrate. A first doped region having the first conductive type is disposed in the doped well. A second doped region having the first conductive type is disposed in the substrate, wherein part of the second doped region is in the doped well, and the remaining part of the second doped region is separate from the doped well. A front terminal electrically connects the first doped region. A back terminal is disposed on a back side of the substrate.

The ESD protection device of the present invention has an equivalent positive clamp voltage and negative clamp voltage. Accordingly, a good protection result can be reached.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 3 schematically illustrate a method of forming an ESD protection device according to the present invention.

FIG. 4 depicts a top view of the ESD protection device illustrated in FIG. 2 according to a first embodiment of the present invention.

FIG. 5 depicts numerous examples of top views of the first doped region according to a preferred embodiment of the present invention.

FIG. 6 depicts numerous examples of top views of the second doped region according to a preferred embodiment of the present invention.

FIG. 7 depicts a top view of the ESD protection device illustrated in FIG. 2 according to a second embodiment of the present invention.

FIG. 8 depicts numerous examples of top views of the sub-doped regions according to a preferred embodiment of the present invention.

FIG. 9 shows an equivalent circuit of the ESD protection device illustrated in FIG. 3.

FIG. 10 shows electric characteristics of the ESD protection device illustrated in FIG. 3.

### DETAILED DESCRIPTION

FIG. 1 to FIG. 3 schematically illustrate a method of forming an ESD protection device according to the present invention. As shown in FIG. 1, a substrate 10 having a first conductive type is provided. The substrate 10 is usually a semiconductor substrate, such as Si. The first conductive type may be P type or N type. The substrate 10 has a front side 12 and a back side 14. An isolation structure 16 is formed on the front side 12 of the substrate 10 so as to define an active region 18 on the substrate 10. The isolation structure 16 may be a shallow trench isolation (STI) or a field oxide (FOX), surrounding as a whole to be an electric isolation. Later, a doped well 20 is formed within the active region 18 on the substrate 10. The doped well 20 has a second conductive type different from the first conductive type. The second conductive type may be N type or P type. For example, when the first conductive type is P type, the second conductive type is N type; when the first conductive type is N type, the second conductive type is P type. The subsequent descriptions take the first conductive type as P type and the second conductive type as N type as an example.

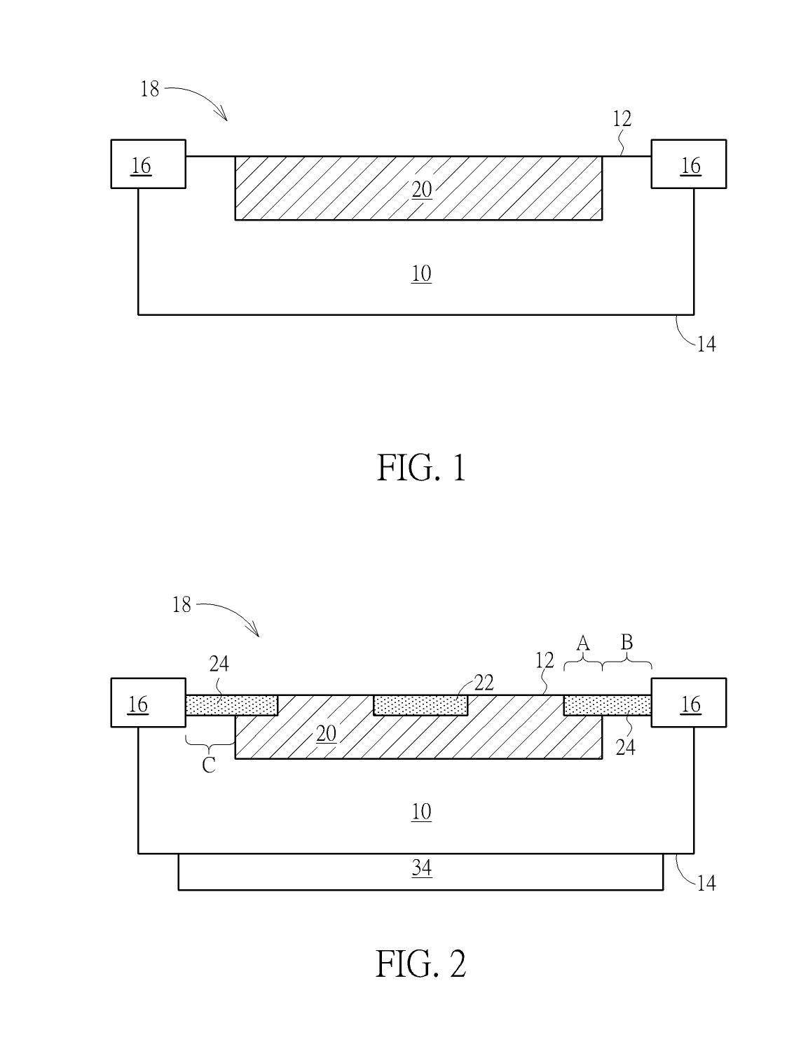

As shown in FIG. 2, a dopant implantation process is performed to simultaneously form a first doped region 22 and a second doped region 24. The first doped region 22 and the second doped region 24 are both of the first conductive type. In other words, the conductive type of the first doped region 22 and the second doped region 24 are the same as the substrate. The methods to form the doped region are well known to persons of ordinary skill in the art; therefore, details will not be discussed here. Furthermore, because the first doped region 22 and the second doped region 24 are formed by the same implantation process, the dopant concentration of the first doped region 22 and the dopant concentration of the second doped region 24 are substantially identical. The dopant concentration of the first doped region 22 and the dopant concentration of the second doped region 24 are preferably between E14 and E15 ions/cm². The first doped region 22 is within the doped well 20 disposed at the active region 18. Preferably, the first doped region 22 is entirely disposed within the doped well 20 and surrounded by the doped well 20. The second doped region 24 is disposed within the active region 18 of the substrate 10. Moreover, the second doped region 24 is defined into a first portion A and a second portion B. The portion A is disposed in and overlaps the doped well 20. The portion B is separate from the doped well 20. In other words, the second doped region 24 overlaps part of the doped well 20 and a region C of the substrate 10. The region C of the substrate does not have the doped well 20 disposed therein. Moreover, the first doped region 22 and the second doped region 24 do not contact each other.

As shown in FIG. 3, a dielectric layer 26 is formed to cover the front side 12 of the substrate 10. Later, a front terminal 28 is formed to penetrate the dielectric layer 26 and electrically connect to the first doped region 22. The front terminal 28 preferably includes a conductive plug 30 disposed in the dielectric layer 26 and a conductive pad 32 disposed on the dielectric layer 26. Then, a back terminal 34 is formed on the back side 14 of the substrate 10. The back terminal 34 can be a conductive pad. At this point, an ESD protection device 100 of the present invention is completed.

Please refer to FIG. 2 again. An ESD protection device of the present invention includes a substrate 10 having a first conductive type. The substrate 10 is usually a semiconductor substrate, such as Si. The first conductive type may be P type or N type, wherein the dopant concentration of the substrate is between E14 and E15 ions/cm². The substrate 10 has a front side 12 and a back side 14. An isolation structure 16 is disposed on the front side 12 of the substrate 10 so as to define an active region 18 on the substrate 10. The isolation structure 16 maybe a shallow trench isolation (STI) or a field oxide (FOX), surrounding as a whole to be an electric isolation. A doped well 20 is disposed within the active region 18 on the substrate 10. The doped well 20 has a second conductive type different from the first conductive type, wherein a dopant concentration of the doped well is between E12 and E15 ions/cm². The second conductive type may be N type or P type. For example, when the first conductive type is P type, the second conductive type is N type; when the first conductive type is N type, the second conductive type is P type. The subsequent descriptions take the first conductive type as P type and the second conductive type as N type as an example.

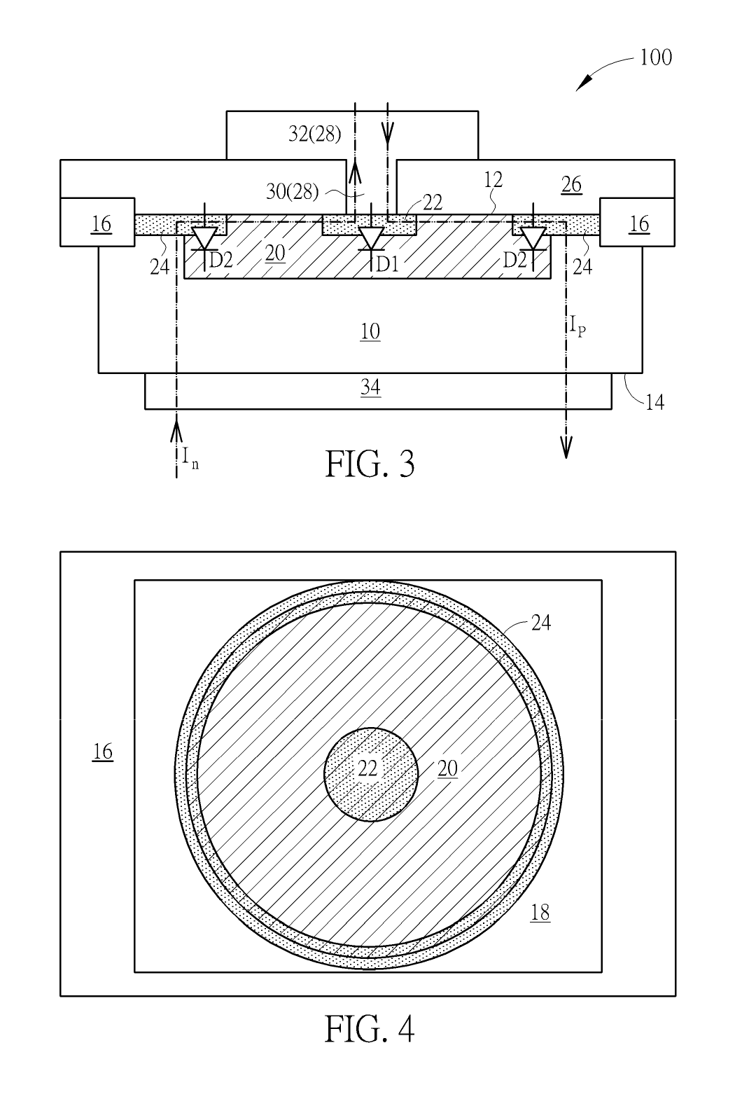

FIG. 4 depicts a top view of the ESD protection device illustrated in FIG. 2 according to a first embodiment of the present invention. Please refer to FIG. 2 and FIG. 4 together. A first doped region 22 having the first conductive type is disposed within the doped well 20. Preferably, the first doped region 22 is entirely disposed within the doped well 20 and surrounded by the doped well 20. The second doped region 24 having the first conductive type is disposed within the active region 18 of the substrate 10. Moreover, the second doped region 24 is defined into a first portion A and a second portion B. The portion A is disposed in and overlaps the doped well 20. The portion B is separate from the doped well 20. In other words, the second doped region 24 overlaps part of the doped well 20 and a region C of the substrate 10. The region C of the substrate 10 does not have the doped well 20 disposed therein. Moreover, the first doped region 22 and the second doped region 24 do not contact each other. The second doped region 24 does not directly contact any circuits. Moreover, because the first doped region 22 and the second doped region 24 are both the first conductive type, the first doped region 22 and the second doped region 24 have the same conductive type as the substrate 10. The depth of the second doped region 24 may be deeper or shallower than the doped well 20.

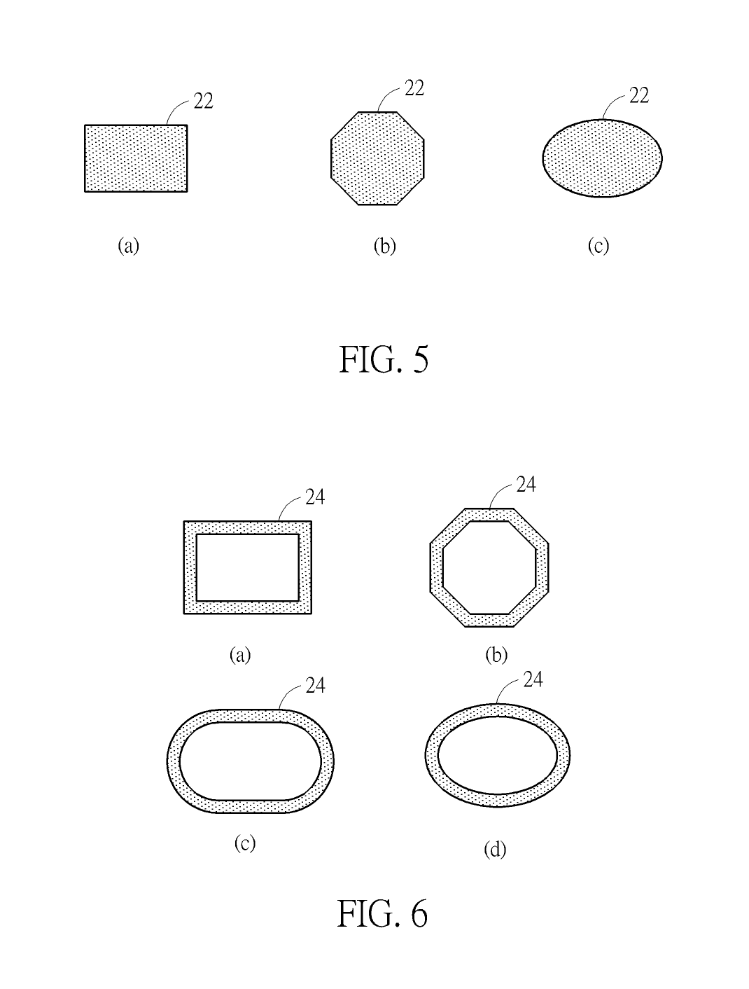

The top view of the first doped region 22 may be circular as shown in FIG. 4, but is not limited to this shape. FIG. 5 depicts numerous top views of the first doped region according to a preferred embodiment of the present invention. Three examples—example (a), example (b) and example (c)—are illustrated in FIG. 5. Each example illustrates a different top view of the first doped region 22. As shown in example (a), the top view of the first doped region 22 may be rectangular. As shown in example (b), the top view of the first doped region 22 may be octangular. As shown in example (c), the top view of the first doped region 22 maybe oval. Numerous modifications and alterations of the shapes illustrated in FIG. 5 should also be considered to come under the claimed field of the present invention.

The top view of the second doped region 24 maybe a closed loop such as a circular ring, which is illustrated in FIG. 4, but is not limited to this shape. FIG. 6 depicts numerous top views of the second doped region according to a preferred embodiment of the present invention. There are four examples—example (a), example (b), example (c) and example (d)—illustrated in FIG. 6. Each example illustrates a different top view of the second doped region 24. As shown in example (a), the top view of the second doped region 24 may be a rectangular ring. As shown in example (b), the top view of the second doped region 24 may be an octangular ring. As shown in example (c), the top view of the second doped region 24 may be a racetrack shape. As shown in example (d), the top view of the second doped region 24 may be an oval ring. Numerous modifications and alterations of the shapes illustrated in FIG. 6 of the present invention should be considered to come under the claimed field of the present invention.

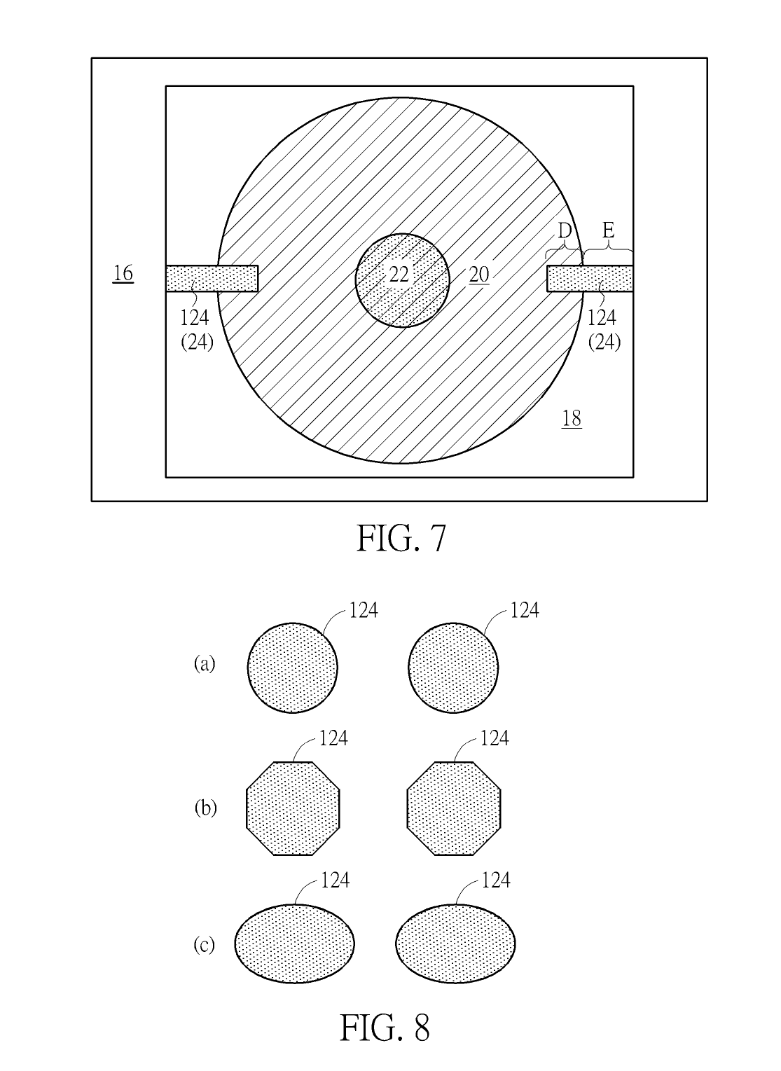

FIG. 7 depicts a top view of the ESD protection device illustrated in FIG. 2 according to a second embodiment of the present invention. Please refer to FIG. 2, FIG. 4 and FIG. 7 together. The difference between FIG. 4 and FIG. 7 is that the second doped region 24 further includes at least one sub-doped region 124 disposed at one side of the first doped region 22. The number of sub-doped regions 124 may be more than one and may surround the first doped region 22. The sub-doped regions 124 do not contact each other. For example, the second doped region 24 may include two sub-doped regions 124 disposed at two sides of the first doped region 22. These sub-doped regions 124 do not contact each other. Each sub-doped region 124 has the first conductive type and is disposed in the active region 18 of the substrate 10. Each sub-doped region 124 has a first portion D disposed in the doped well 20, and a second portion E separate from the doped well 20.

The top view of the sub-doped regions 124 may be rectangular as shown in FIG. 7, but they are not limited to this shape. FIG. 8 depicts numerous top views of the sub-doped regions 124 according to a preferred embodiment of the present invention. There are three examples—example (a), example (b) and example (c)—illustrated in FIG. 8. Each example illustrates a different top view of the sub-doped regions 124. As shown in example (a), the top view of the sub-doped region 124 may be circular. As shown in example (b), the top view of the sub-doped region 124 may be octangular. As shown in example (c), the top view of the sub-doped region 124 may be oval. Numerous modifications and alterations of the shapes illustrated in FIG. 8 of the present invention should be considered to come under the claimed field of the present invention. Moreover, each sub-doped region 124 may have a different shape. For example, one sub-doped region 124 is circular while the other sub-doped region 124 is rectangular. Furthermore, the shape of the first doped region 22 is not limited to circular; the shape of the first doped region 22 can be any of the other shapes illustrated in FIG. 5.

Please refer to FIG. 3 again. As shown in the diagram, the ESD protection device 100 further includes a dielectric layer 26 which covers the front side 12 of the substrate 10. A front terminal 28 penetrates the dielectric layer 26 and electrically connects to the first doped region 22. The front terminal 28 preferably includes a conductive plug 30 disposed in the dielectric layer 26 and a conductive pad 32 disposed on the dielectric layer 26. A back terminal 34 is then formed on the back side 14 of the substrate 10. The back terminal 34 can be a conductive pad. The front terminal 28 usually electrically connects to a device which is protected by the ESD protection device 100.

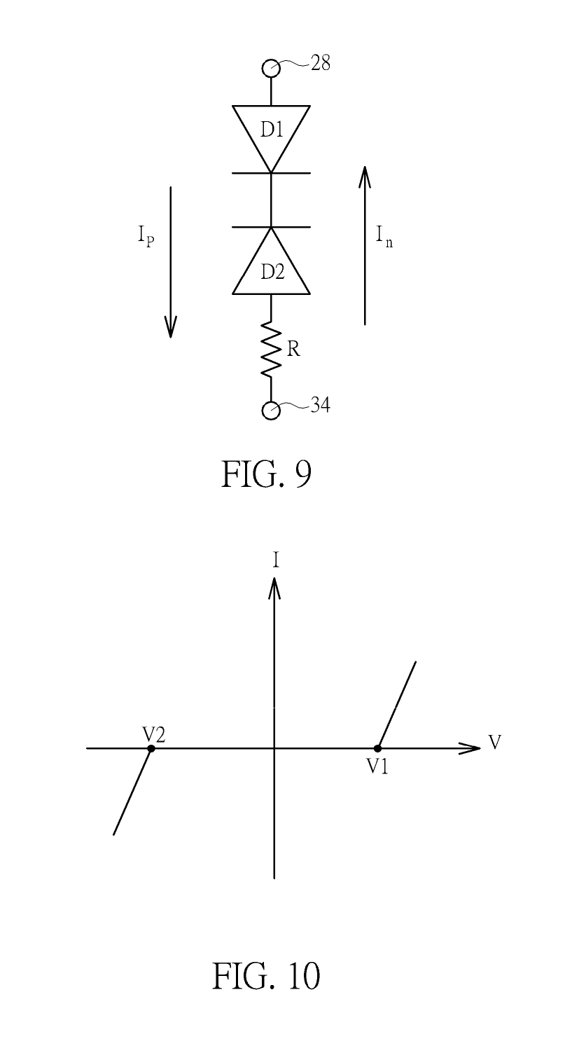

FIG. 9 shows an equivalent circuit of the ESD protection device illustrated in FIG. 3. FIG. 10 shows a current-voltage curve of the ESD protection device illustrated in FIG. 3. Please refer to FIG. 3 and FIG. 9 together. When the first conductive type is P type, and the second conductive type is N type, a diode D1 is formed between the first doped region 22 and the doped well 20. A diode D2 is formed between the second doped region and the doped well 20. Other elements on the conduction path such as the front terminal 28, the back terminal 34, and the substrate 10 form an equivalent resistance R.

As shown in FIG. 9 and FIG. 10, the ESD protection device 100 has a positive clamp voltage V1 and a negative clamp voltage V2. The positive clamp voltage V1 is equal to the forward voltage of the diode D1 plus the breakdown voltage of the diode D2 and the voltage drop through the equivalent resistance R. A negative clamp voltage V2 is equal to the forward voltage of the diode D2 plus the breakdown voltage of the diode D1 and the voltage drop through the equivalent resistance R. It is noteworthy that the positive clamp voltage V1 equals the negative clamp voltage V2.

Please refer to FIG. 9 and FIG. 10 again. When positive electrostatic pulses are received from the front terminal 28, and the voltage between the front terminal 28 and the back terminal 34 exceeds the positive clamp voltage V1 of the ESD protection device 100, a positive current Iₚ flows from the front terminal 28 through the diode D1, the diode D2 and the substrate 10 to the back terminal 34. When negative electrostatic pulses are received from the front terminal 28, and the voltage between the front terminal 28 and the back terminal 34 exceeds the negative clamp voltage V2 of the ESD protection device 100, a positive current Iₙ flows from the back terminal 34 through the substrate 10, the diode D2 and the diode D1 to the front terminal 28.

The ESD protection device 100 of the present invention has an equivalent positive clamp voltage V1 and negative clamp voltage V2. This can be achieved by adjusting the size of an overlapping area of the second doped region 24 and the doped well 20, and varying the dopant concentration of the second doped region 24 and the doped well 20.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An ESD protection device, comprising:
a substrate having a first conductive type;
a doped well having a second conductive type disposed in the substrate;
a first doped region disposed in the doped well and having the first conductive type;
a second doped region disposed in the substrate and having the first conductive type, wherein part of the second doped region is in the doped well, and the remaining part of the second doped region is separate from the doped well;
a front terminal electrically connected to the first doped region; and
a back terminal disposed on a back side of the substrate.

2. The ESD protection device of claim 1, wherein the second doped region simultaneously overlaps part of the doped well and a region in the substrate which does not have the doped well disposed therein.

3. The ESD protection device of claim 1, wherein the first doped region is disposed entirely within the doped well.

4. The ESD protection device of claim 1, wherein a top view of the first doped region comprises a circle, a rectangle, an oval or an octangle.

5. The ESD protection device of claim 1, wherein the second doped region is a closed loop.

6. The ESD protection device of claim 5, wherein a top view the second doped region comprises a circular ring, a rectangular ring, an octangular ring, an oval ring or a racetrack shape.

7. The ESD protection device of claim 1, wherein the second doping region further comprises two sub-doped regions disposed at two opposite sides of the first doped region, and the sub-doped regions are separate from each other.

8. The ESD protection device of claim 7, wherein each top view of the sub-doped regions comprises a circle, a rectangle, an oval or an octangle.

9. The ESD protection device of claim 1, wherein the first conductive type is P type and the second conductive type is N type.

10. The ESD protection device of claim 1, wherein the first conductive type is N type and the second conductive type is P type.

11. The ESD protection device of claim 1, wherein a dopant concentration of the substrate is between E14 and E15 ions/cm².

12. The ESD protection device of claim 1, wherein a dopant concentration of the doped well is between E12 and E15 ions/cm².

13. The ESD protection device of claim 1, wherein a dopant concentration of the second doped region is between E14 and E15 ions/cm².

14. The ESD protection device of claim 1, further comprising an isolation structure disposed on the substrate to define an active region.

15. The ESD protection device of claim 14, wherein the doped well, the first doped region, and the second doped region are disposed within the active region.
